(19) United States
(12) Patent Application Publication
(10) Pub. No.: US 2009/0130831 A1
(43) Pub. Date: May 21, 2009

(54) SEMICONDUCTOR DEVICE AND METHOD OF FABRICATING THE SAME

(76) Inventor: Ji-Hwan Park, Cheonan-si (KR)

Correspondence Address: SHERR & VAUGHN, PLLC, 620 HERNDON PARKWAY, SUITE 200, HERNDON, VA, 20170, US

(21) Appl. No.: 12/254,020

(22) Filed: Oct. 20, 2008

(30) Foreign Application Priority Data
Nov. 16, 2007 (KR) 10-2007-0117087

(51) Int. Cl. H01L 21/425

(52) U.S. Cl. 438/530; 257/E21.473

(57) ABSTRACT

A method for fabricating a semiconductor device having a CMOS transistor including a gate electrode with low resistance. In the CMOS transistor in accordance with embodiments, the impurities implanted into the gate electrode have a higher density than the impurities implanted into the source/drain region. Embodiments also reduce the amount of impurities included in channel regions.

The present application claims priority under 35 U.S.C. §119 to Korean Patent Application No. 10-2007-0117087 (filed on Nov. 16, 2007), which is hereby incorporated by reference in its entirety.

### BACKGROUND

As an information processing technology has been developed, a semiconductor device requires high integration and a small size. Further, it is necessary to reduce the resistance of a gate electrode and prevent impurities from infiltrating into a channel region.

### SUMMARY

Embodiments relate to a semiconductor device and a method of fabricating the same that reduces the resistance of a gate electrode and also prevents impurities from infiltrating into a channel region.

Embodiments relate to a method of fabricating a semiconductor device that may include at least one of the following: forming a gate plate by implanting conductive impurities into a wafer; and then bonding the gate plate to a semiconductor substrate; and then forming a gate electrode by patterning the bonded gate plate.

Embodiments relate to a method that may include at least one of the following: forming a first gate region into a wafer by selectively implanting high-density n-type impurities into the wafer; and then forming a second gate region on the same plane and contacting the first gate region by implanting high-intensity p-type impurities into the wafer; and then performing a first heat treatment on the wafer including the first gate region and the second gate region; and then forming a hydrogen layer in the first gate region and the second gate region; and then forming an oxide layer over a semiconductor substrate having a first active region and a second active region; and then bonding the wafer to the semiconductor substrate at an interface between the uppermost surface of the first and second gate regions and the oxide layer such that the first gate region corresponds spatially to the first active region and the second gate region corresponds spatially to the second active region; and then removing a portion of the wafer at the hydrogen layer to expose the surface of the first and second gate regions; and then simultaneously forming a first gate structure in the first active region and a second gate structure in the second active region by patterning the first and second gate regions and the oxide layer; and then simultaneously forming first LDD regions spaced apart in the first active region of the semiconductor substrate and second LDD regions spaced apart in the second active region of the semiconductor substrate; and then simultaneously forming first sidewall spacers on the first gate structure and second sidewall spacers on the second gate structure; and then forming a first source/drain region in the first active region and a second source/drain region in the second active region.

Embodiments relate to a method that may include at least one of the following: forming a first gate region into a wafer by selectively implanting high-density n-type impurities into the wafer; and then forming a second gate region having an uppermost surface that is coplanar to the uppermost surface of the first gate region by implanting high-intensity p-type impurities into the wafer; and then forming a hydrogen layer in the first gate region and the second gate region; and then forming an oxide layer over a semiconductor substrate having a first active region and a second active region; and then bonding the wafer to the semiconductor substrate at an interface between the uppermost surface of the first and second gate regions and the oxide layer such that the first gate region corresponds spatially to the first active region and the second gate region corresponds spatially to the second active region; and then removing a portion of the wafer at the hydrogen layer; and then simultaneously forming a first gate structure in the first active region and a second gate structure in the second active region by patterning the first and second gate regions and the oxide layer.

Embodiments relate to a semiconductor device that may include at least one of the following: a gate electrode formed on and/or over a semiconductor substrate; and a source/drain region formed at one side of the gate electrode such that the gate electrode includes conductive impurities having a higher density than the source/drain region.

In the semiconductor device and the method of fabricating the same in accordance with embodiments, conductive impurities are implanted into the gate plate and the gate plate is bonded to the semiconductor substrate. Accordingly, it is possible to implant a large amount of conductive impurities into the gate plate. Thus, the resistance of the gate electrode is reduced by the large amount of conductive impurities. After the conductive impurities are implanted into the gate plate, the gate plate is bonded to the semiconductor substrate. Accordingly, it is possible to prevent conductive impurities from infiltrating into a channel region.

### DRAWINGS

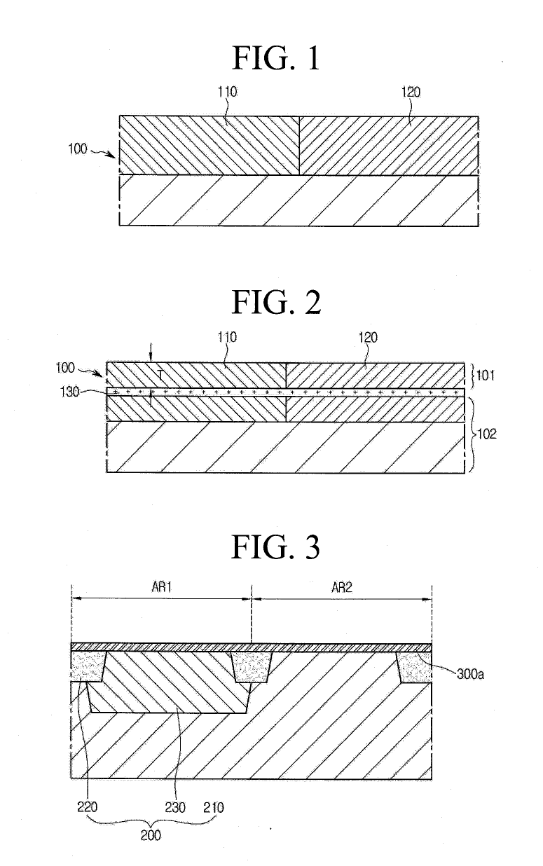

Example FIGS. 1 to 6 illustrate semiconductor device and a method of fabricating a semiconductor device in accordance with embodiments.

### DESCRIPTION

Reference will now be made in detail to embodiments, examples of which are illustrated in the accompanying drawings. Wherever possible, the same reference numbers will be used throughout the drawings to refer to the same or like parts.

FIGS. 1 to 6 illustrate cross-sectional views showing the steps of according to an embodiment of the present invention.

As illustrated in example FIG. 1, a method of fabricating a semiconductor device in accordance with embodiments includes selectively implanting high-density n-type impurities into a silicon wafer to form first gate region 110. In order to form first gate region 110, a photoresist film is formed on and/or over the silicon wafer and then patterned through an exposure and development process to form a photoresist pattern. Then, high-intensity n-type impurities are implanted using the photoresist pattern as a mask. For example, phosphorus (P) may be used as the n-type impurities. The n-type impurities are implanted at a dosage in a range between approximately 1E16 atoms/cm² to 1E17 atoms/cm² at an energy in a range between approximately 10 to 50 keV. Then, high-intensity p-type impurities are selectively implanted into the silicon wafer having first gate region 110 to form second gate region 120 on the same plane as first gate region 120 and contacting first gate region 110. In order to form second gate region 120, a photoresist pattern exposing a region exclusive of first gate region 110 is formed on the silicon wafer. High-intensity p-type impurities are then implanted using the photoresist pattern as a mask. For example, boron (B) may be used as the p-type impurities, and the p-type impurities are implanted at a dosage in a range between approximately 1E16 atoms/cm² to 1E17 atoms/cm² at an energy in a range between approximately 10 to 50 keV. Then, the silicon wafer having first gate region 110 and second gate region 120 undergoes heat treatment at a temperature in a range between approximately 1000 to 1200° C. for a time in a range between approximately 10 to 30 seconds in a rapid temperature process (RTP) chamber.

As illustrated in example FIG. 2, a bonding blocking material is then injected into the heat-treated silicon wafer (hereinafter, referred to as a gate plate) 100. The bonding blocking material decreases a bonding force between atoms included in gate plate 100. The bonding blocking material may be, for example, hydrogen (H). The bonding blocking material is injected into an area parallel to the uppermost surface of gate plate 100 to form bonding force weakening layer 130. Bonding force weakening layer 130 is parallel to the uppermost surface of gate plate 100 to thereby divide gate plate 100 into upper portion 101 and lower portion 102. Further, a predetermined distance T between the uppermost surface of gate plate 100 and the uppermost surface of bonding force weakening layer 130 may be in a range between approximately 2000 to 4000 Å. Meaning, bonding blocking material can be implanted at a depth in a range between approximately 2000 to 4000 Å.

As illustrated in example FIG. 3, semiconductor substrate 200 is formed, and then oxide film 300a is formed on and/or over semiconductor substrate 200. In order to form semiconductor substrate 200, an STI process or LOCOS process is performed on the silicon substrate implanted with p-type impurities to form device isolation film 220 therein defining first active region AR1 and second active region AR2. Then, p-type impurities are selectively implanted into first active region AR1 to form p-well 230. Accordingly, region 210 including n-type impurities, device isolation film 220 and semiconductor substrate 200 including p-well 230 are formed. Then, oxide film 300a is formed on and/or over semiconductor substrate 200 by a thermal oxidation process, a CVD process or the like.

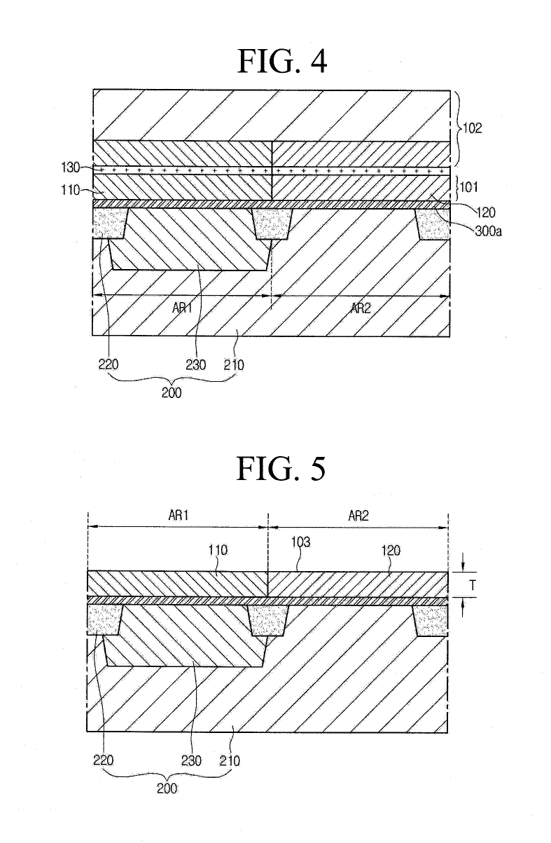

As illustrated in example FIG. 4, gate plate 100 and semiconductor substrate 200 having oxide film 300a are bonded to each other such that first gate region 110 corresponds spatially and contacts first active region AR1 and second gate region 120 corresponds spatially and contacts second active region AR2. Gate plate 100 and semiconductor substrate 200 are then cleaned by performing a cleaning process that may include a washing process and a drying process. Then, after thin films made of ions and molecules, for example, OH⁻, H⁺, H₂O, H₂ and O₂ are formed on and/or over the uppermost surface of gate plate 100 and the uppermost surface of oxide film 300a, the two uppermost surfaces are closely adhered to each other. Accordingly, gate plate 100 and semiconductor substrate 200 are temporarily bonded to each other by van der Waals forces. Then, the temporarily bonded gate plate 100 and semiconductor substrate 200 undergo heat treatment at a temperature in a range between approximately 700 to 900° C. Gate plate 100 and semiconductor substrate 200 are strongly coupled to each other by inter-diffusion between the atoms of gate plate 100 and oxide film 300a.

As illustrated in example FIG. 5, a physical impact is applied to bonding force weakening layer 130 to separate lower portion 102 of gate plate 100. Gate plate 100 is removed while gate plate 100 having a thickness T in a range between approximately 2000 to 4000 Å remains. Alternatively, lower portion 102 of gate plate 100 may be removed by a CMP process or the like while the bonding force weakening material is not injected into gate plate 100. Alternatively, bonding force weakening material is injected after bonding gate plate 100, and then lower portion 102 of gate plate 100 may be separated. Then, cut section 103 of gate plate 100 may be planarized by performing a rapid temperature annealing (RTA) process.

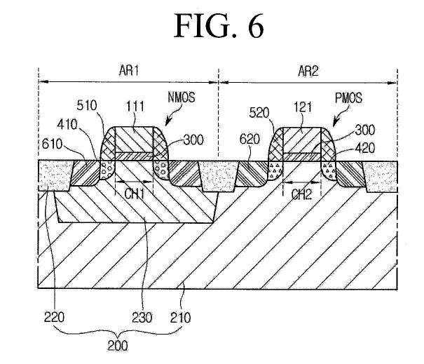

As illustrated in example FIG. 6, gate plate 100 having no lower portion 102 and oxide film 300a are patterned, thereby forming gate electrodes and gate insulating film 300. The gate electrodes include first gate electrode 111 formed in first active region AR1 and second gate electrode 121 formed in second active region AR2. Then, a rapid temperature annealing (RTA) process may be performed to planarized the uppermost surfaces of first gate electrode 111 and second gate electrode 121. Then, low-density n-type impurities are selectively implanted into first active region AR1 to form first LDD regions 410. The n-type impurities are implanted using first gate electrode 111 as a mask. A pair of first LDD regions 410 are formed spaced apart from each other, and a region between first LDD region 410 corresponds to first channel region CH1. Then, low-density p-type impurities are selectively implanted into second active region AR2 to form second LDD regions 420. The p-type impurities are implanted using second gate electrode 121 as a mask. A pair of second LDD regions 420 are formed spaced apart from each other, and a region between second LDD regions 420 corresponds to second channel region CH2.

A nitride film is then formed on and/or over the entire surface of semiconductor substrate 200, and then the nitride film is etched by anisotropic etching to thereby form first spacer 510 on the sidewall surface of first gate electrode 111 and second spacer 520 on the sidewall surface of second gate electrode 121. Then, high-density n-type impurities are selectively implanted into first active region AR1 to form first source/drain region 610. The high-density n-type impurities are implanted using first gate electrode 111 and first spacer 510 as masks. Then, high-density p-type impurities are selectively implanted into second active region AR2 to form second source/drain region 620. The high-density p-type impurities are implanted using second gate electrode 121 and second spacer 520 as masks. Accordingly, a CMOS transistor including a NMOS transistor and a PMOS transistor is formed.

In the CMOS transistor in accordance with embodiments, the impurities implanted into the gate electrode and the impurities implanted into the source/drain region have different densities. Meaning, the impurities implanted into the gate electrode have a higher density than the impurities implanted into the source/drain region. Accordingly, the gate electrode has a low resistance. Further, after impurities are implanted into the gate plate, the gate plate is bonded to the semiconductor substrate to form a gate electrode. Thus, the impurities do not infiltrate into a lower portion of the gate electrode. Therfore, it is possible to reduce the amount of impurities included in channel regions CH1 and CH2. Therefore, a CMOS transistor in accordance with embodiments has enhanced overall performance.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method of fabricating a semiconductor device comprising:
forming a gate plate by implanting conductive impurities into a wafer; and then
bonding the gate plate to a semiconductor substrate; and then
forming a gate electrode by patterning the bonded gate plate.

2. The method of claim 1, wherein forming the gate plate comprises:
forming a first gate region by selectively implanting first conductive impurities into the wafer; and then
forming a second gate region by selectively implanting second conductive impurities into the wafer.

3. The method of claim 2, further comprising:
performing a heat treatment process on the gate plate implanted with the first conductive impurities and the second conductive impurities.

4. The method of claim 2, wherein the gate plate is bonded to the semiconductor substrate such that the first gate region corresponds spatially to a first active region of the semiconductor substrate and the second gate region corresponds spatially to a second active region of the semiconductor substrate.

5. The method of claim 4, wherein the first active region of the semiconductor substrate is a region implanted with second conductive impurities and the second active region is a region implanted with first conductive impurities.

6. The method of claim 1, wherein bonding the gate plate to the semiconductor substrate comprises:
cleaning the gate plate and the semiconductor substrate; and then
adhering the gate plate and the semiconductor substrate to each other; and then
performing a heat treatment process on the gate plate and the semiconductor substrate after adhering the gate plate and the semiconductor substrate to each other.

7. The method of claim 1, wherein forming the gate electrode comprises:
cutting an upper portion of the gate plate after bonding the gate plate to the semiconductor substrate; and then
patterning the gate plate after cutting the upper portion of the gate plate.

8. The method of claim 7, wherein forming the gate electrode further comprises injecting a bonding blocking material into a section of the wafer implanted with impurities.

9. The method of claim 8, further comprising:
cutting an upper portion of the gate plate along the section injected with the bonding blocking material.

10. The method of claim 8, wherein the bonding blocking material is hydrogen.

11. The method of claim 7, wherein the upper portion of the gate plate is cut to have a thickness in a range between approximately 2000 Å to 4000 Å.

12. The method of claim 7, further comprising performing a heat treatment process on the gate plate after cutting the upper portion of the gate plate.

13. The method of claim 7, further comprising: performing a heat treatment process on the gate electrode after patterning the gate plate.

14. A method comprising:
forming a first gate region into a wafer by selectively implanting high-density n-type impurities into the wafer; and then
forming a second gate region on the same plane and contacting the first gate region by implanting high-intensity p-type impurities into the wafer; and then
performing a first heat treatment on the wafer including the first gate region and the second gate region; and then
forming a hydrogen layer in the first gate region and the second gate region; and then
forming an oxide layer over a semiconductor substrate having a first active region and a second active region; and then
bonding the wafer to the semiconductor substrate at an interface between the uppermost surface of the first and second gate regions and the oxide layer such that the first gate region corresponds spatially to the first active region and the second gate region corresponds spatially to the second active region; and then
removing a portion of the wafer at the hydrogen layer to expose the surface of the first and second gate regions; and then
simultaneously forming a first gate structure in the first active region and a second gate structure in the second active region by patterning the first and second gate regions and the oxide layer; and then
simultaneously forming first LDD regions spaced apart in the first active region of the semiconductor substrate and second LDD regions spaced apart in the second active region of the semiconductor substrate; and then
simultaneously forming first sidewall spacers on the first gate structure and second sidewall spacers on the second gate structure; and then
forming a first source/drain region in the first active region and a second source/drain region in the second active region.

15. The method of claim 14, wherein forming the hydrogen layer comprises injecting hydrogen into an area parallel to the uppermost surface of the first and second gate regions.

16. The method of claim 15, wherein forming the hydrogen layer divides the first and second gate regions into an upper gate region portion and a lower gate region portion.

17. The method of claim 14, wherein forming the hydrogen layer comprises forming a predetermined distance between the uppermost surface of the first and second gate regions and the uppermost surface of hydrogen layer.

18. The method of claim 17, wherein the predetermined distance is in a range between approximately 2000 to 4000 Å.

19. The method of claim 14, further comprising performing a heat treatment process on the first and second gate structures.

20. A method comprising:
forming a first gate region into a wafer by selectively implanting high-density n-type impurities into the wafer; and then
forming a second gate region having an uppermost surface that is coplanar to the uppermost surface of the first gate region by implanting high-intensity p-type impurities into the wafer; and then
forming a hydrogen layer in the first gate region and the second gate region; and then forming an oxide layer over a semiconductor substrate having a first active region and a second active region; and then
bonding the wafer to the semiconductor substrate at an interface between the uppermost surface of the first and second gate regions and the oxide layer such that the first gate region corresponds spatially to the first active region and the second gate region corresponds spatially to the second active region; and then
removing a portion of the wafer at the hydrogen layer; and then
simultaneously forming a first gate structure in the first active region and a second gate structure in the second active region by patterning the first and second gate regions and the oxide layer.
